(19) United States
(12) Patent Application Publication
(10) Pub. No.: US 2026/0282668 A1
(43) Pub. Date: Sep. 17, 2026

(54) METHOD OF MANUFACTURING DISPLAY DEVICE AND ELECTRONIC DEVICE INCLUDING DISPLAY DEVICE

(71) Applicant: Samsung Display Co., Ltd., Yongin-Si (KR)

(72) Inventors: Goo Jin JUNG, Yongin-si (KR); Young Mok KIM, Yongin-si (KR); Sung Hyun PARK, Yongin-si (KR); Han-Min YOON, Yongin-si (KR); Ji Soo HAN, Yongin-si (KR)

(21) Appl. No.: 19/564,585

(22) Filed: Mar. 12, 2026

(30) Foreign Application Priority Data
Mar. 13, 2025 (KR) 10-2025-0032987

(51) Int. Cl. H10K 59/123; H10K 59/12

(52) U.S. Cl. CPC H10K 59/123; H10K 59/1201

(57) ABSTRACT

In a method of manufacturing a display device, a via insulating layer is formed on a base substrate. A preliminary pixel electrode including a metal layer that has a protrusion is formed on the via insulating layer. A photoresist layer covering the preliminary pixel electrode is formed on the via insulating layer. An upper portion of the photoresist layer is removed to expose an upper portion of the protrusion. The exposed upper portion of the protrusion may be etched to form a pixel electrode including the metal layer in which a height of the protrusion is reduced. A light-emitting portion is formed on the pixel electrode. A counter electrode is formed on the light-emitting portion.

### CROSS-REFERENCE TO RELATED APPLICATION

This application claims priority to Korean Patent Application No. 10-2025-0032987 filed on March 13, 2025, in the Korean Intellectual Property Office (KIPO), the entire disclosure of which is incorporated by reference herein.

### BACKGROUND

### 1. Field

Embodiments of the present disclosure relate to a method of manufacturing a display device and an electronic device including a display device. More particularly, embodiments of the present disclosure relate to a method of manufacturing a display device including a transistor and electrodes, and electronic device including the display device.

### 2. Descriptions of the Related Art

In a display device such as an organic light emitting diode (OLED) display device and a liquid crystal display (LCD) device, a display substrate including, e.g., a thin film transistor (TFT) and various wirings may be provided. A display structure including electrodes and emission layers may be formed on the display substrate.

For example, a pixel electrode connecting the TFT and the display structure may be provided. Recently, various constructions of the TFT and the pixel electrode for stable implementation of a high-resolution display device have been researched

### SUMMARY

According to an aspect of the present disclosure, there is provided a display device having improved electrical and structural reliability.

According to an aspect of the present disclosure, there is provided a method of manufacturing a display device having improved electrical and structural reliability.

According to an aspect of the present disclosure, there is provided an electronic device including a display device having improved electrical and structural reliability.

In a method of manufacturing a display device, a via insulating layer may be formed on a base substrate. A pixel electrode may be formed on the via insulating layer. The pixel electrode may be formed by forming preliminary pixel electrode including a metal layer that has a protrusion on the via insulating layer, forming a photoresist layer covering the preliminary pixel electrode on the via insulating layer, removing an upper portion of the photoresist layer to expose an upper portion of the protrusion, and etching the exposed upper portion of the protrusion to form the pixel electrode including the metal layer in which a height of the protrusion is reduced. A light-emitting portion may be formed on the pixel electrode. A counter electrode is formed on the light-emitting portion.

In some embodiments, the metal layer may include aluminum (Al).

In some embodiments, in the formation of the pixel electrode, a conductive layer including a transparent conductive oxide may be formed on the metal layer in which the height of the protrusion is reduced.

In some embodiments, the preliminary pixel electrode may further include an intermediate insulating layer formed on the metal layer and covering the protrusion. The conductive layer may be formed on the intermediate insulating layer to contact a side surface of the metal layer.

In some embodiments, in removing the upper portion of the photoresist layer to expose the upper portion of the protrusion, a portion of the intermediate insulating layer covering the upper portion of the protrusion may be removed.

In some embodiments, a recess may be formed in a portion where the exposed upper portion of the protrusion is etched, and a tip portion surrounding the recess may be formed by a remaining portion of the protrusion.

In some embodiments, before forming the light-emitting portion, a pixel defining layer partially covering the pixel electrode may be formed. In the formation of the pixel defining layer. a protective layer, a blocking layer and a filling layer may be sequentially formed on the pixel electrode. An upper portion of the filling layer may be polished until a top surface of the blocking layer is exposed to form a filling pattern. The blocking layer and the protective layer may be partially etched to form an opening exposing a top surface of the pixel electrode.

In some embodiments, in the formation of the pixel defining layer, a first insulating layer, a second insulating layer and a third insulating layer that includes an insulating inorganic oxide, an insulating inorganic nitride and an insulating inorganic oxide, respectively, may be sequentially formed on a stopper layer and the filling pattern. In the formation of the opening, the third insulating layer, the second insulating layer and the first insulating layer may be partially etched before partially etching the blocking layer and the protective layer to form a third insulating pattern, a second insulating pattern and a first insulating pattern.

In some embodiments, removing the upper portion of the photoresist layer to expose the upper portion of the protrusion may be performed by an etch-back process.

In a method of manufacturing a display device, a via insulating layer may be formed on a base substrate. A pixel electrode including a metal layer that has a convex portion may be formed on the via insulating layer. A protective layer covering the pixel electrode and having a convex insulating portion may be formed on the convex portion. A photoresist layer may be formed on the protective layer. The convex insulating portion may be removed while removing an upper portion of the photoresist layer. The protective layer may be etched to form an opening exposing a top surface of the pixel electrode. A light-emitting portion may be formed on the exposed pixel electrode. A counter electrode may be formed on the light-emitting portion.

In some embodiments, removing the convex insulating portion while removing an upper portion of the photoresist layer may be performed by an etch-back process.

In some embodiments, after removing the convex insulating portion while removing the upper portion of the photoresist layer, the remaining photoresist layer may be removed. A blocking layer may be formed on the protective layer. A filling layer that fills a space from which the remaining photoresist layer is removed may be formed on the blocking layer. The filling layer may be polished until a top surface of the blocking layer is exposed to form a filling pattern.

In some embodiments, in the formation of the opening, the blocking layer may be etched before etching the protective layer.

In some embodiments, the metal layer may include aluminum (Al).

In some embodiments, in the formation of the pixel electrode, a conductive layer covering the convex portion and including a transparent conductive oxide may be formed on the metal layer.

In some embodiments, in the formation of the pixel electrode, an intermediate insulating layer covering the convex portion may be formed between the conductive layer and the metal layer. The conductive layer may contact a side surface of the metal layer.

An electronic device may include a display device, a memory, and a processor executing data contained in the memory to control an operation of the display device. The display device may include a base substrate, a transistor structure on the base substrate, a pixel electrode including a metal layer electrically connected to the transistor structure and including a tip portion or a convex portion that protrudes from a top surface thereof, a light-emitting portion on the pixel electrode, and a counter electrode on the light-emitting portion.

In some embodiments, the metal layer may include the tip portion, and has a recess surrounded by the tip portion. The pixel electrode may include an intermediate insulating layer covering a side surface of the tip portion on the top surface of the metal layer, and a conductive layer including a transparent conductive oxide, filling the recess on the intermediate insulating layer and contacting a side surface of the metal layer.

In some embodiments, the metal layer may include the convex portion. The pixel electrode may further include an intermediate insulating layer covering the convex portion on the top surface of the metal layer, and a conductive layer disposed on the intermediate insulating layer, including a transparent conductive oxide and contacting a side surface of the metal layer. Each of the intermediate insulating layer and the conductive layer may have a convex curved surface on the convex portion.

In some embodiments, the electronic device may include virtual reality or augmented reality glasses, a smartphone, a tablet personal computer (PC), a laptop, a television, a desk monitor, smart glasses, a head-mounted display, a smart watch, or a vehicle display.

In a display device according to embodiments of the present disclosure, electrical and mechanical defects due to a hillock of a metal layer generated when a pixel electrode or a reflective electrode is formed may be suppressed.

According to embodiments, loss of the metal layer and generation of voids may be prevented, and a display device having high luminance/high resolution may be implemented.

### BRIEF DESCRIPTION OF THE DRAWINGS

FIG. 1 is a schematic plan view illustrating a display device according to embodiments.

FIG. 2 is an equivalent pixel circuit diagram of a display device according to embodiments.

FIG. 3 is a cross-sectional view illustrating a display device according to embodiments.

FIG. 4 is a cross-sectional view illustrating a display device according to embodiments.

FIGS. 5 and 6 are schematic cross-sectional views illustrating a light-emitting device according to embodiments.

FIGS. 7, 8, 9, 10, 11, 12, 13, 14, 15, 16, 17 and 18 are schematic cross-sectional views illustrating a method of manufacturing a display device according to embodiments.

FIGS. 19, 20, 21, 22 and 23 are schematic cross-sectional views illustrating a method of manufacturing a display device according to embodiments.

FIG. 24 is an exploded perspective view of a display device according to embodiments.

FIG. 25 is a block diagram of an electronic device in accordance with an embodiment.

FIG. 26 is a schematic diagram of electronic devices in accordance with various embodiments.

### DETAILED DESCRIPTION OF THE EMBODIMENTS

Hereinafter, embodiments of the present invention will be described in more detail with reference to the attached drawings. The same reference numerals can l be used for indicating the same elements in the drawings, and repeated descriptions of the same elements can be omitted. Embodiments disclosed in the attached drawings are examples, and is to be understood to include all modifications, equivalents and substitutes included in the spirit and technical scope of the present invention.

The terms "on", "connected", "coupled," etc., used herein refers to a direct placement/connection/combination, and also refers to a case where another element is interposed two different elements.

The terms such as "first", "second", "below", "under", "above," "on," etc., are used in a relative sense to distinguish different elements or positions, and do not specify an absolute position or an absolute order.

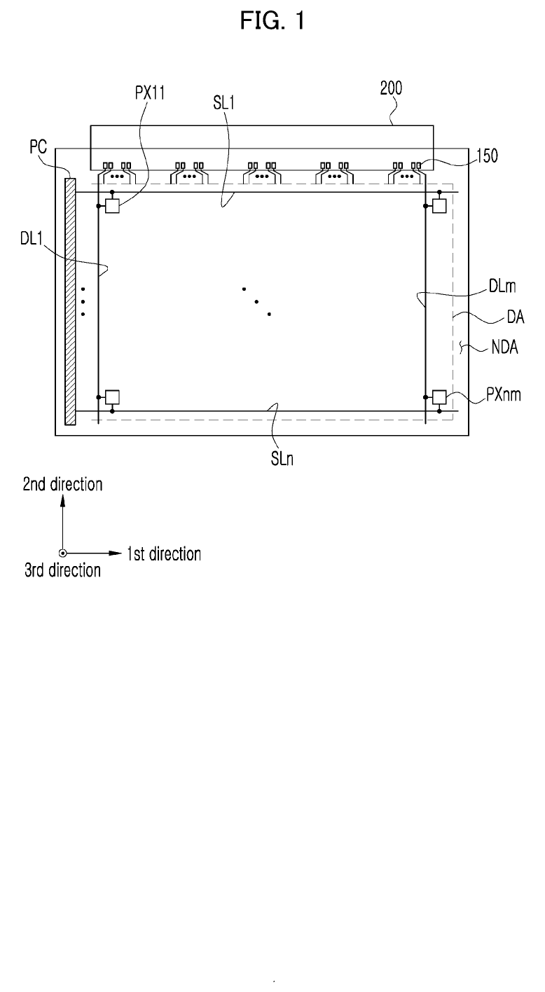

FIG. 1 is a schematic plan view illustrating a display device according to embodiments.

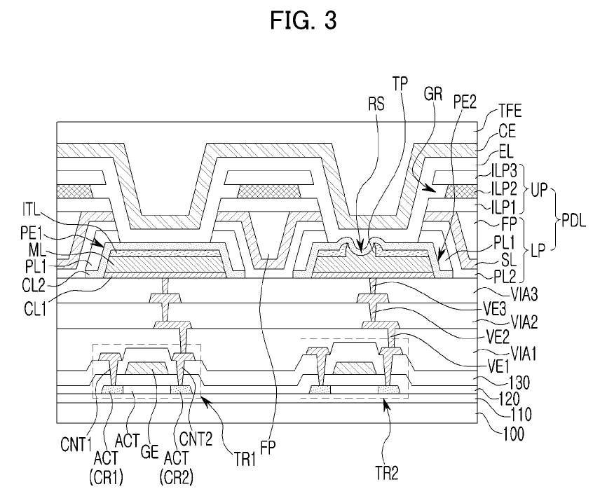

In FIG. 1, a first direction and a second direction may refer to two directions parallel to a top surface of a base substrate 100 (see FIG. 3) and intersecting each other. For example, the first direction and the second direction may be orthogonal to each other.

For example, the first direction may correspond to an X-direction (e.g., a row direction or a width direction) of the display device, and the second direction may correspond to a Y-direction (a column direction or a length direction) of the display device.

The third direction may be perpendicular to the first direction and the second direction. The third direction may correspond to a Z-direction (a thickness direction) of the display device.

In the accompanying drawings, the above definition of the directions may be equally applied.

Referring to FIG. 1, the display device may include a display area DA and a non-display area NDA. The display area DA may provide a surface on which an image of the display device is substantially displayed and a user's touch/command is input. The non-display area NDA may substantially correspond to a bezel area or a peripheral area of the display device. In an embodiment, the display area DA may be substantially surrounded by the non-display area NDA.

The base substrate 100 may also include the display area DA and the non-display area NDA. A plurality of pixels PX11 to PXnm may be arranged on the display area DA of the base substrate 100.

In example embodiments, pixel circuits including scan lines SL1 to SLn (or gate lines) disposed in first to n^{th} rows, and data lines DL1 to DLm disposed in first to m^{th} columns may be arranged on the base substrate 100 of the display device. Each of the pixels PX11 to PXnm may be connected to a scan line of a corresponding row among a plurality of scan lines SL1 to SLn and a data line of a corresponding column among a plurality of data lines DL1 to DLm.

Each of the pixels PX11 to PXnm may further include a pixel circuit including a transistor and a light-emitting element as described below. Although not illustrated in detail in FIG. 1, the pixel circuit may further include wirings such as a power line, a ground line, etc.

FIG. 1 illustrates that the data lines DL1 to DLm extend in the second direction and the scan lines SL1 to SLn extend in the first direction, but the construction of the data lines and the gate lines is not limited to that illustrated in FIG. 1. In FIG. 1, a shape of each pixel PX11 to PXnm is illustrated as a square for convenience of illustration, but the shape of each pixel is not limited to that illustrated in FIG. 1.

A peripheral circuit PC may be disposed in the non-display area NDA corresponding to a peripheral area of the display area DA. For example, the peripheral circuit PC may include a gate driving circuit. The gate driving circuit may be integrated into the display panel DP by an oxide semiconductor gate (OSG) driver circuit process, an amorphous silicon gate (OSG) driver circuit process, or a polysilicon gate (PSG) driver circuit process.

The peripheral circuit PC may further include a data driver, a light-emitting driver, a power voltage generator, a timing controller, or the like.

The display device may further include a printed circuit board 200. Pads 150 of the pixel circuit may be disposed in one end portion of the non-display area NDA. The printed circuit board 200 may be electrically connected to the pixel circuit through the pads 150. For example, the printed circuit board 200 may be electrically connected to the pads 150 by a heat-compression process using a conductive intermediate structure such as an anisotropic conductive film (ACF).

An integrated circuit (IC) such as a data driving circuit may be disposed on the printed circuit board 200. In some embodiments, an integrated circuit (IC) chip in the form of a chip-on-film (COF) may be mounted on the printed circuit board 200.

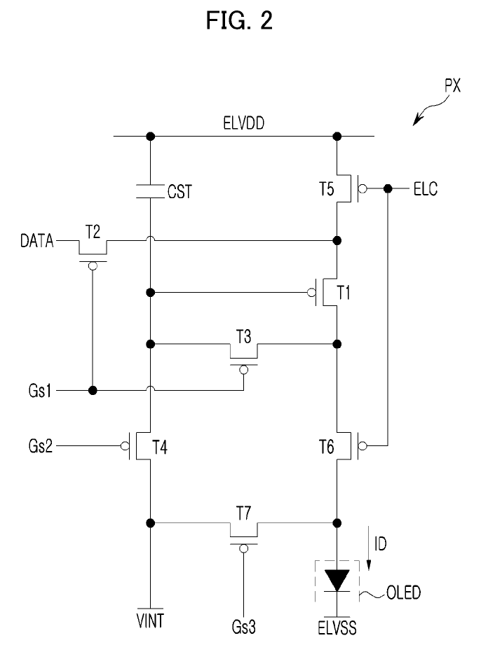

FIG. 2 is an equivalent pixel circuit diagram of a display device according to embodiments.

Referring to FIG. 2, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal and a second terminal. The gate terminal may be connected to the storage capacitor CST. The first terminal may be connected to the second transistor T2. The second terminal may be connected to the sixth transistor T6. The first transistor T1 may generate a driving current ID based on a voltage difference between the gate terminal and the first terminal. For example, the first transistor T1 may be referred to as a driving transistor.

The second transistor T2 may include a gate terminal, a first terminal and a second terminal. The gate terminal of the second transistor T2 may receive a first gate signal Gs1. The second transistor T2 may be turned on or turned off in response to the first gate signal Gs1. The first terminal of the second transistor T2 may receive a data voltage DATA. The second transistor T2 may provide the data voltage DATA to the first terminal of the first transistor T1 in response to the first gate signal Gs1. For example, the second transistor T2 may be referred to as a switching transistor.

The third transistor T3 may include a gate terminal, a first terminal and a second terminal. The gate terminal may receive the first gate signal Gs1. The first terminal may be connected to the gate terminal of the first transistor T1. The second terminal may be connected to the second terminal of the first transistor T1. The third transistor T3 may compensate for a threshold voltage of the first transistor T1. For example, the third transistor T3 may serve as a compensation transistor.

The fourth transistor T4 may include a gate terminal, a first terminal and a second terminal. The gate terminal may receive a second gate signal Gs2. The first terminal may be connected to the gate terminal of the first transistor T1. The second terminal may receive an initialization voltage VINT. The fourth transistor T4 may initialize the gate terminal of the first transistor T1.

The fifth transistor T5 may include a gate terminal, a first terminal and a second terminal. The gate terminal may receive an emission control signal ELC. The first terminal may receive a high-power supply voltage ELVDD. The second terminal may be connected to the first transistor T1.

The sixth transistor T6 may include a gate terminal, a first terminal and a second terminal. The gate terminal may receive the emission control signal ELC. The first terminal may be connected to the first transistor T1. The second terminal may be connected to an organic light-emitting diode OLED. The sixth transistor T6 may transfer the driving current ID to the organic light emitting diode OLED in response to the emission control signal ELC.

The seventh transistor T7 may include a gate terminal, a first terminal and a second terminal. The gate terminal may receive a third gate signal Gs3. The first terminal may be connected to the organic light-emitting diode OLED. The second terminal may receive the initialization voltage VINT. The seventh transistor T7 may initialize the organic light-emitting diode OLED.

The storage capacitor CST may include a first terminal and a second terminal. The first terminal may receive the high-power supply voltage ELVDD. The second terminal may be connected to the gate terminal of the first transistor T1,

The organic light-emitting diode OLED may include a first terminal and a second terminal. The first terminal may be connected to the sixth transistor T6. The second terminal may receive a low-power supply voltage ELVSS. The organic light-emitting diode OLED may emit light based on the driving current ID.

In FIG. 2, a structure of 7T1C including seven thin film transistors and one storage capacitor CST in each pixel PX is illustrated, but the pixel structure of the display device disclosed herein is not limited thereto.

For example, each pixel PX may include two or more transistors, and may have a structure such as 2T1C, 5T1C, 6T1C, 5T2C, 6T2C, or the like.

FIG. 3 is a schematic cross-sectional view illustrating a display device according to embodiments.

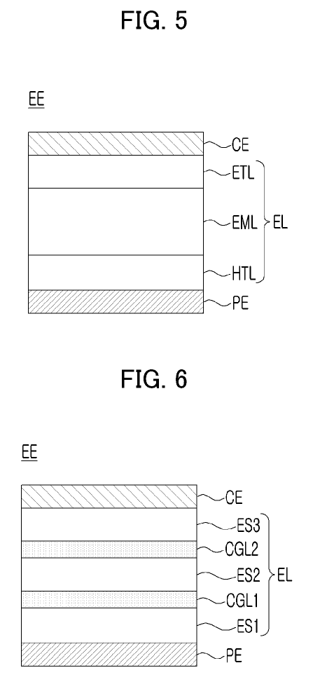

Referring to FIG. 3, the display device may include a base substrate 100, a pixel circuit including transistor structures TR1 and TR2, and a light-emitting element EE (see FIGS. 5 and 6).

For convenience of descriptions, FIG. 3 illustrates structures corresponding to only two neighboring pixels.

The base substrate 100 may serve as a back-plane substrate of a display device. A glass substrate, a ceramic substrate or a plastic substrate may be used as the base substrate 100. In some embodiments, the base substrate 100 may include a polymer material having transparency and flexibility. In this case, the base substrate 100 may be used in a transparent flexible display device.

For example, the base substrate 100 may include a polymer material such as polyimide, polysiloxane, an epoxy resin, an acrylic resin, polyester, or the like. In an embodiment, the base substrate 100 may include polyimide.

In some embodiments, the base substrate 100 may be a silicon substrate prepared from a silicon wafer.

A buffer layer 110 may be formed on a top surface of the base substrate 100. Moisture penetrating through the base substrate 100 may be blocked by the buffer layer 110, and diffusion of impurities between the base substrate 100 and structures formed on the base substrate 100 may also be blocked by the buffer layer 110. The buffer layer 110 may be formed entirely over the display area DA and the non-display area NDA of the base substrate 100, and may entirely cover the top surface of the base substrate 100.

The buffer layer 110 may include, e.g., an inorganic insulating material such as silicon oxide, silicon nitride, silicon oxynitride, or the like. These may be used alone or in a combination thereof.

In some embodiments, the buffer layer 110 may have a stacked structure including a silicon oxide layer and a silicon nitride layer. The buffer layer 110 may be formed by a deposition process such as a chemical vapor deposition (CVD) process, a sputtering process, an atomic layer deposition (ALD) process, or the like, to include the above-mentioned inorganic insulating material.

In some embodiments, the buffer layer 110 may include an organic layer, and may have a multi-layered structure of an organic layer and an inorganic layer.

The pixel circuit may include wirings including the scan lines and the data lines described with reference to FIG. 1, and transistor structures TR1 and TR2 electrically connected to the wirings. Each of the transistor structures TR1 and TR2 may be electrically connected to the light-emitting element EE.

The transistor structures TR1 and TR2 may each include an active layer ACT, a gate insulation layer 120, and a gate electrode GE. The transistor structure TR1 and TR2 may further include contact electrodes CNT1 and CNT2.

The active layer ACT may be disposed on the buffer layer 110, and may be patterned by a photo-lithography process to be repeatedly/regularly arranged at each pixel. The active layer ACT may include a silicon compound such as polysilicon or amorphous silicon. A p-type dopant or an n-type dopant may be doped in a partial region of the active layer ACT, and the active layer ACT may include a source region, a drain region, and a channel region.

The active layer ACT may include an oxide semiconductor such as indium gallium zinc oxide (IGZO), zinc tin oxide (ZTO), or indium tin zinc oxide (ITZO).

The gate insulation layer 120 may be formed on an active layer ACT, and the gate electrode GE may be stacked on the gate insulation layer 120. As illustrated in FIG. 3, the gate insulation layer 120 may be included commonly throughout the first and second transistor structures TR1 and TR2, or pixels of different colors.

In an embodiment, the gate insulation layer 120 may partially cover each active layer 110, and may be formed in a pattern shape independently at each of the first and second transistor structures TR1 and TR2.

The gate electrode GE may overlap the channel region of the active layer ACT in the third direction. A scan signal may be transmitted from the scan line through the gate electrode GE.

The gate insulation layer 120 may be formed by the above-mentioned deposition process to include an inorganic insulating material such as silicon oxide, silicon nitride, silicon oxynitride, or a metal oxide.

In some embodiments, a p-type dopant or an n-type dopant may be doped into the active layer ACT by an ion implantation process using the gate electrode GE as an ion implantation mask. Accordingly, a first contact region CR1 and a second contact region CR2 may be formed at one side portion and the other side portion of the active layer ACT, respectively. The first contact region CR1 and the second contact region CR2 may correspond to a source region and a drain region, respectively.

A portion of the active layer ACT overlapping the gate electrode GE in a vertical direction (the third direction) and disposed between the first contact region CR1 and the second contact region CR2 may be defined as the channel region.

In some embodiments, the gate insulation layer 120 may be formed as a pattern covering the channel region by an etching process using the gate electrode GE as an etching mask. When the active layer ACT includes the oxide semiconductor, hydrogen (H) included in an insulating interlayer 130 may be diffused or transferred to the active layer ACT during the formation of the insulating interlayer 130. Accordingly, a carrier concentration may be increased by hydrogen to form the contact regions CR1 and CR2 at the side portions of the active layer ACT.

The insulating interlayer 130 covering the gate electrode GE and the gate insulation layer 120 may be formed on the active layer ACT. The insulating interlayer 130 may be formed by the above-mentioned deposition process to include an inorganic insulating material such as silicon oxide, silicon nitride, silicon oxynitride, or the like. The insulating interlayer 130 may be formed in a single-layered structure or a multi-layered structure including different materials.

The contact electrodes CNT1 and CNT2 which may be in contact with or electrically connected to the active layer ACT may be formed on the insulating interlayer 130.

The contact electrode may include a first contact electrode CNT1 that may be connected to or in contact with the first contact region CR1 of the active layer ACT, and a second contact electrode CNT2 that may be connected to or in contact with the second contact region CR2 of the active layer ACT. In some embodiments, the first contact electrode CNT1 and the second contact electrode CNT2 may serve as a source electrode and a drain electrode, respectively.

According to embodiments, the insulating interlayer 130 may be partially etched to form contact holes. For example, contact holes exposing each of the first contact region CR1 and the second contact region CR2 may be formed. The contact holes may also extend through the gate insulation layer 120.

A metal layer filling the contact holes may be formed on the insulating interlayer 130, and then may be partially etched to form the first contact electrode CNT1 and the second contact electrode CNT2. For example, a data signal may be transferred from the data line through the first contact electrode CNT1.

The gate electrode GE and the contact electrodes CNT1 and CNT2 may include a metal such as Ag, Mg, Al, W, Cu, Ni, Cr, Mo, Ti, Pt, Ta, Nd, Sc, an alloy thereof, or a nitride thereof. The gate electrode GE and the contact electrodes CNT1 and CNT2 may be formed by a deposition process such as a sputtering process.

The gate electrode GE and the contact electrodes CNT1 and CNT2 may be formed in a multi-layered structure (e.g., a Ti layer-an Al layer-a Ti layer).

As described above, the first and second transistor structures TR1 and TR2 may be formed to form a thin film transistor (TFT)-array. The first transistor structure TR1 and the second transistor structure TR2 may be transistor structures included in pixels of different colors.

In a non-limiting example, at least one of the first transistor structure TR1 and the second transistor structure TR2 may be a transistor structure corresponding to a red pixel and a green pixel, respectively. In this case, although not illustrated in FIG. 3, a third transistor structure corresponding to a blue pixel may be arranged together with the first transistor structure TR1 and the second transistor structure TR2.

In an embodiment, the first transistor structure TR1 and the second transistor structure TR2 may be transistor structures included in pixels of the same color.

A first via insulation layer VIA1 covering the contact electrodes CNT1 and CNT2 may be formed on the insulating interlayer 130. The first via insulation layer VIA1 may be a planarization layer of the TFT-array.

The first via insulation layer VIA1 may be partially removed to form a first via hole exposing a top surface of the contact electrode (e.g., the second contact electrode CNT2). An electrode layer filling the first via hole may be formed on a top surface of the first via insulation layer VIA1, and then may be partially etched to form a first via electrode VE1.

A second via insulation layer VIA2 covering the first via electrode VE1 may be formed on the first via insulation layer VIA1. The second via insulation layer VIA2 may be partially removed to form a second via hole exposing a top surface of the first via electrode VE1. An electrode layer filling the second via hole may be formed on a top surface of the second via insulation layer VIA2, and then may be partially etched to form the second via electrode VE2.

A third via insulation layer VIA3 covering the second via electrode VE2 may be formed on the second via insulation layer VIA2. The third via insulation layer VIA3 may be partially removed to form a third via hole exposing a top surface of the second via electrode VE2. An electrode layer may be filled in the third via hole to form a third via electrode VE3 filling the third via hole. The third via electrode VE3 may also be formed on a top surface of the third via insulation layer VIA3.

The first to third via insulation layers VIA1, VIA2 and VIA3 may be formed as organic insulation layers. For example, the first to third via insulating layers VIA1, VIA2 and VIA3 may include an organic polymer material such as polyimide, an epoxy resin, an acrylic resin, polyester, a siloxane resin, benzocyclobutene (BCB), or the like. For example, the first to third via insulation layers VIA1, VIA2 and VIA3 may be formed by a coating process such as a spin coating process.

The electrode layers for forming the via electrodes VE1, VE2 and VE3 may include a metal such as Ag, Mg, Al, W, Cu, Ni, Cr, Mo, Ti, Pt, Ta, Nd, Sc, an alloy thereof, or a nitride thereof. The electrode layers may be formed by a deposition process such as a sputtering process.

Each of first and second pixel electrodes PE1 and PE2 may be in contact with or electrically connected to the third via electrode VE3 on the third via insulation layer VIA3. Accordingly, the first and second pixel electrodes PE1 and PE2 may be electrically connected to the contact electrode (e.g., the second contact electrode CNT2) of the first and second transistor structures TR1 and TR2, respectively, through the via electrodes VE1, VE2 and VE3.

FIG. 3 illustrates the via insulation layer of a triple-layered structure and the via electrode of a triple-layered structure, but the construction of the display device of the present disclosure is not limited to that illustrated in FIG. 3. For example, the via insulation layer/the via electrode may have a single-layered structure or a double-layered structure, or four or more via insulation layers/via electrodes may be included.

The first and second pixel electrodes PE1 and PE2 may be provided as an anode of the light-emitting element EE of a corresponding pixel. According to embodiments, the pixel electrode PE may serve as a reflective electrode including a metal layer ML.

Each of the pixel electrodes PE1 and PE2 may further include a conductive layer. According to embodiments, each of the pixel electrodes PE1 and PE2 may include a multi-layered structure including a first conductive layer CL1, a metal layer ML, and a second conductive layer CL2 sequentially stacked on the top surface of the third via insulation layer VIA3.

The first conductive layer CL1 may include a metal different from that of the metal layer ML. According to embodiments, the first conductive layer CL1 may include a metal having higher chemical stability and adhesion properties than a metal included in the metal layer ML. In some embodiments, the first conductive layer CL1 may include titanium (Ti) or tantalum (Ta). For example, the first conductive layer CL1 may include titanium (Ti).

The metal layer ML may be substantially provided as a reflective layer of the pixel electrode PE. According to embodiments, the metal layer ML may include aluminum (Al).

The second conductive layer CL2 may include a transparent conductive oxide. For example, the second conductive layer CL2 may include a transparent conductive oxide such as indium tin oxide (ITO), indium zinc oxide (IZO), zinc oxide (ZnO), indium tin oxide (ITZO), or the like. In some embodiments, the second conductive layer CL2 may be formed of ITO.

According to embodiments, an intermediate insulating layer ITL may be included between the second conductive layer CL2 and the metal layer ML. The intermediate insulating layer ITL may be included as a protective layer or a capping layer of the metal layer ML before forming the second conductive layer CL2. In some embodiments, the intermediate insulating layer ITL may include an insulating oxide such as silicon oxide.

The second conductive layer CL2 may entirely cover a stacked structure of the first conductive layer CL1, the metal layer ML and the intermediate insulating layer ITL on the third via insulation layer VIA3. Accordingly, the second conductive layer CL2 may be in contact with a side surface of the metal layer ML to provide a side contact structure. Thus, an aperture ratio or an effective area of the pixel region may be increased by using the second conductive layer CL2 including a transparent conductive oxide. The second conductive layer CL2 may also be in contact with a side surface of the first conductive layer CL1.

A thickness of the metal layer ML may be greater than each thickness of the first and second conductive layers CL1 and CL2. Accordingly, low resistance and high reflection properties of the pixel electrodes PE1 and PE2 may be effectively implemented.

According to embodiments of the present disclosure, the metal layer ML of the pixel electrode PE may include a tip portion TP protruding toward a light-emitting portion EL. A recess RS concave in a direction toward the first conductive layer CL1 or the third via insulating layer VIA3 may be formed by the tip portion TP.

According to embodiments, the metal layer ML of at least one of the first pixel electrode PE1 and the second pixel electrode PE2 may include the tip portion TP. In some embodiments, both the metal layers ML of the first pixel electrode PE1 and the second pixel electrode PE2 may include the tip portion TP.

For convenience of description, FIG. 3 illustrates that only the metal layer ML included in the second pixel electrode PE2 includes the tip portion TP.

A pixel defining layer PDL that may substantially define a pixel region or a light-emitting region may be formed on the pixel electrodes PE1 and PE2. The pixel defining layer PDL may be formed to at least partially expose top surfaces (e.g., a top surface of the second conductive layer CL2) of the pixel electrodes PE1 and PE2. The pixel defining layer PDL may cover peripheral portions of the pixel electrodes PE1 and PE2.

According to embodiments, the pixel defining layer PDL may include a lower stack LP and an upper stack UP. Each of the lower stack LP and the upper stack UP may include a plurality of insulating layers.

The lower stack LP may cover the peripheral portions of the pixel electrodes PE1 and PE2, and may fill a space between the neighboring pixel electrodes PE1 and PE2. The lower stack LP may include a first protective layer PL1, a second protective layer PL2, a stopper layer SL and a filling pattern FP, which are sequentially stacked on the top surface of the second conductive layer CL2.

The first protective layer PL1 and the second protective layer PL2 may include an insulating inorganic oxide such as silicon oxide. In some embodiments, the first protective layer PL1 and the second protective layer PL2 may be substantially merged into a single protective layer.

The stopper layer SL may include an insulating inorganic nitride such as silicon nitride. As described later, the stopper layer SL may be provided as a polishing stopper layer.

The first protective layer PL1, the second protective layer PL2, and the stopper layer SL may be conformally formed along a profile of surfaces of neighboring pixel electrodes PE1 and PE2 and the third via insulation layer VIA3 between the neighboring pixel electrodes PE1 and PE2. Accordingly, each of the first protective layer PL1, the second protective layer PL2, and the stopper layer SL may have a stepped structure, and a trench-shaped space may be formed in the stopper layer SL.

The lower stack LP may include a filling pattern FP. According to embodiments, the filling pattern FP may include an organic insulating material. In some embodiments, the filling pattern FP may include an organic siloxane-based material such as tetraethyl orthosilicate (TEOS) or an organic silane-based material.

The filling pattern FP may be provided as a planarization layer planarizing a structure disposed thereunder. According to embodiments, a top surface of the stopper layer SL and a top surface of the filling pattern FP may be located substantially in the same plane. For example, the top surface of the stopper layer SL and the top surface of the filling pattern FP may form substantially a single plane.

The upper stack UP may include a first insulating pattern ILP1, a second insulating pattern ILP2, and a third insulating pattern ILP3 sequentially stacked on a top surface of the lower stack LP.

Each of the first insulating pattern ILP1 and the third insulating pattern ILP3 may include an inorganic insulating oxide such as silicon oxide. The second insulating pattern ILP2 may include an inorganic insulating nitride such as silicon nitride.

In some embodiments, a width of the second insulating pattern ILP2 may be less than a width of each of the first insulating pattern ILP1 and the third insulating pattern ILP3. For example, the upper stack UP may include a groove GR. The groove GR may be defined by a top surface of the first insulating pattern ILP1, a side surface of the second insulating pattern ILP2, and a bottom surface of the third insulating pattern ILP3.

The light-emitting portion EL may be formed on top surfaces of the pixel electrodes PE1 and PE2 exposed by the pixel defining layer PDL and a surface of the pixel defining layer PDL. The light-emitting portion EL may include an organic light-emitting layer that may be independently patterned for each of a red pixel region, a green pixel region, and a blue pixel region to generate lights of different colors for each pixel.

In an embodiment, the light-emitting portion EL may fill the groove GR or may conformally extend along a surface of the groove GR. In an embodiment, the light-emitting portion EL may have a discontinuous region at the groove GR.

In an embodiment, the light-emitting portion EL may continuously and commonly extend across a plurality of pixels. In this case, the light-emitting portion EL may include a white light-emitting layer or a blue light-emitting layer. In an embodiment, the light-emitting portion EL may include a plurality of emission layers corresponding to different colors or the same color, and may have a tandem structure.

The light-emitting element EE including the light-emitting portion EL will be described in more detail with reference to FIGS. 5 and 6.

A counter electrode CE may be disposed on the light-emitting portion EL. The counter electrode CE may be a common electrode that may be continuously and commonly provided in a plurality of pixel regions.

The counter electrode CE may be provided as an electron injection electrode or a cathode. The counter electrode CE may include a metal, an alloy, an electrically conductive compound, or the like, having a low work function.

For example, the counter electrode CE may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These may be used alone or in a combination of two or more therefrom.

The counter electrode CE may be formed as a transmissive electrode, a translucent electrode, or a reflective electrode. The counter electrode CE may have a single-layered structure or a multi-layered structure.

The counter electrode CE may be formed by a deposition process such as a sputtering process using a target that may include the above-described conductive material.

The light-emitting element EE may include the pixel electrode PE, the light-emitting portion EL, and the counter electrode CE as described above. The light-emitting element EE may be provided as an organic light-emitting diode (OLED) element.

An encapsulation layer TFE may be formed on the counter electrode CE. The encapsulation layer TFE may be disposed on the pixel defining layer PDL and the light-emitting elements EE to protect the light-emitting elements EE from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)), or any combination thereof; or a combination of the inorganic and organic layers.

The encapsulation layer TFE may be formed in a single-layered structure or a multi-layered structure. In some embodiments, the encapsulation layer TFE may have a sequentially stacked structure of a first inorganic layer, an organic layer, and a second inorganic layer.

In some embodiments, a color control layer (not shown) overlapping the light-emitting portion EL may be disposed on the encapsulation layer TFE. The color control layer may include a color conversion layer including quantum dots and/or a color filter.

In some embodiments, a sensor layer (not shown) such as a touch sensor layer and/or an optical functional layer (not shown) such as a polarizing plate, an anti-reflection layer, an antistatic layer, or the like, may be disposed on the encapsulation layer TFE.

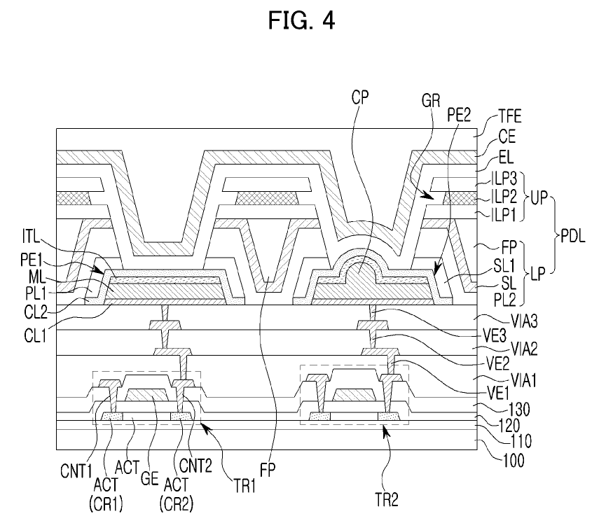

FIG. 4 is a cross-sectional view illustrating a display device according to embodiments. Detailed descriptions on elements and structures substantially the same as or similar to those described with reference to FIG. 3 are omitted.

Referring to FIG. 4, the metal layer ML of the at least one pixel electrode PE may include a convex portion CP. For example, the second pixel electrode PE2 may have a convex curved surface protruding toward the light-emitting portion EL. For example, the metal layer ML may not have the recess RS included in the metal layer ML of FIG. 3.

The intermediate insulating layer ITL, the second conductive layer CL2, the light-emitting portion EL, and the counter electrode CE may also have a convex curved surface on the convex part CP in a direction toward an upper portion or a window of the display device.

FIGS. 5 and 6 are schematic cross-sectional views illustrating a light-emitting element according to embodiments.

Referring to FIG. 5, the light-emitting element EE may include the pixel electrode PE, the counter electrode CE, and the light-emitting portion EL disposed between the pixel electrode PE and the counter electrode CE as described above.

The light-emitting portion EL may include a hole transport layer HTL, an emission layer EML and an electron transport layer ETL. According to embodiments, the hole transport layer HTL, the emission layer EML, the electron transport layer ETL and the counter electrode CE may be sequentially stacked on the top surface of the pixel electrode PE.

The emission layer EML may include an organic light-emitting material having red, green or blue emission properties. For example, the emission layer EML may include a fluorescent host and/or a host for a phosphorescent device, and may further include a fluorescent dopant, a phosphorescent dopant, and/or a thermally activated delayed fluorescence (TADF) dopant.

For example, the hole transport layer HTL may include a hole transporting material such as m-MTDATA (4,4',4"-[tris(3-methylphenyl)phenylamino] triphenylamine), TDATA (4,4'4"-tris(N,N-diphenylamino)triphenylamine), 2-TNATA (4,4',4"-tris[N(2-naphthyl)-N-phenylamino]-triphenylamine), NPB (N,N'-di(naphthalene-l-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), or the like.

For example, the electron transport layer ETL may include an electron transporting material such as Alq₃(tris(8-hydroxyquinolinato)aluminum), TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), or the like.

In some embodiments, the hole transport layer HTL and the electron transport layer ETL may be formed as a common layer continuously extending over a plurality of pixel regions.

In some embodiments, a hole injection layer may be further disposed between the pixel electrode PE and the hole transport layer HTL. An electron injection layer may be further disposed between the counter electrode CE and the electron transport layer ETL.

The layers included in the light-emitting portion EL may be formed by a thermal deposition, an evaporation deposition, a vacuum deposition, a spin coating, an inkjet printing, a laser printing, a casting, a laser thermal transfer, or the like.

Referring to FIG. 6, the light-emitting portion EL may include a plurality of the light-emitting structures. Each of the light-emitting structures may include a hole transport layer, an emission layer and an electron transport layer. According to embodiments, the light-emitting element EE of FIG. 6 may be a light-emitting element having a tandem structure generating a white light or a blue light.

In an embodiment, the light-emitting structures may include a first light-emitting structure ES1, a second light-emitting structure ES2 and a third light-emitting structure ES3.

Charge generation layers CGL1 and CGL2 may be disposed between the neighboring light-emitting structures. The charge generation layers CGL1 and CGL2 may include a p-type charge generation layer and/or an n-type charge generation layer. The charge generation layers CGL1 and CGL2 may include a first charge generation layer CGL1 between the first light-emitting structure ES1 and the second light-emitting structure ES2, and a second charge generation layer CGL2 between the second light-emitting structure ES2 and the third light-emitting structure ES3.

According to embodiments, the first light-emitting structure ES1, the first charge generation layer CGL1, the second light-emitting structure ES2, the second charge generation layer CGL2, the third light-emitting structure ES3 and the counter electrode CE may be sequentially stacked on the top surface of the pixel electrode PE.

FIG. 6 illustrates an example of the light-emitting element EE having a triple-layer tandem structure, but the light-emitting elements EE may have a tandem structure of double-layered or a tandem structure including four or more layers.

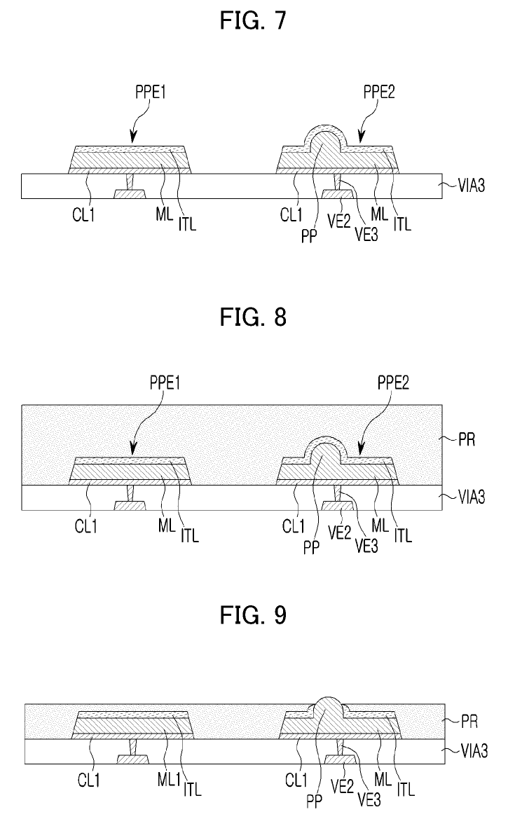

FIGS. 7 to 18 are schematic cross-sectional views illustrating a method of manufacturing a display device according to embodiments. For example, FIGS. 7 to 18 are schematic cross-sectional views illustrating a method of manufacturing a display device described with reference to FIG. 3.

For convenience of illustration and description, detailed illustration of the base substrate 100, and structures and elements between the base substrate 100 and the third via insulating layer VIA3 are omitted in FIGS. 7 to 18.

Referring to FIG. 7, as described with reference to FIG. 3, a TFT-array including the transistor structures TR1 and TR2 may be formed on the base substrate 100.

The first via insulating layer VIA1 covering the first and second transistor structures TR1 and TR2 may be formed, and the first via electrode VE1 may be formed to be connected to each of the contact electrodes included in the first and second transistor structures TR1 and TR2 through the first via insulating layer VIA1.

Thereafter, as described with reference to FIG. 3, the second via insulating layer VIA2, the second via electrode VE2, the third via insulating layer VIA3, and the third via electrode VE3 may be sequentially formed.

A preliminary pixel electrodes PPE1 and PPE2 may be formed on the third via insulation layer VIA3 and the third via electrode VE3.

A first conductive layer CL1, a metal layer ML, and an intermediate insulating layer ITL may be sequentially formed on the third via insulating layer VIA3.

As described above, in some embodiments, the first conductive layer CL1, the metal layer ML, and the intermediate insulating layer ITL may be formed to include Ti, Al, and silicon oxide, respectively. For example, the first conductive layer CL1, the metal layer ML, and the intermediate insulating layer ITL may be formed by a deposition process such as a sputtering process or a CVD process.

Thereafter, the intermediate insulating layer ITL, the metal layer ML, and the first conductive layer CL1 may be sequentially etched by a photo-lithography process to form the first preliminary pixel electrode PPE1 and the second preliminary pixel electrode PPE2 separated from each other.

A protrusion PP may be formed from the metal layer ML included in at least one of the first preliminary pixel electrode PPE1 and the second preliminary pixel electrode PPE2. For example, during the photo-lithography process or a subsequent annealing process, the protrusion PP having a convex curved surface may be grown in a direction toward the intermediate insulating layer ITL due to a hillock phenomenon of Al included in the metal layer ML. Accordingly, the protrusion having a convex curved shape may also be formed in the intermediate insulating layer ITL.

Referring to FIG. 8, a photoresist layer PR covering the preliminary pixel electrodes PPE1 and PPE2 may be formed on the via insulation layer VIA3. The photoresist layer PR may entirely cover the preliminary pixel electrodes PPE1 and PPE2 by a coating process such as a spin coating process.

Referring to FIG. 9, an upper portion of the photoresist layer PR may be removed by an etch-back process.

According to embodiments, an upper portion of the protrusion included in the intermediate insulating layer ITL may also be removed by the etch-back process. Accordingly, an upper portion of the protrusion PP formed from the metal layer ML of the second preliminary pixel electrode PPE2 may be partially exposed.

In some embodiments, the photoresist layer PR may remain on the first preliminary pixel electrode PPE1 at which the protrusion PP is not formed by the etch-back process. For example, the photoresist layer PR may entirely cover the first preliminary pixel electrode PPE1 even after the etch-back process.

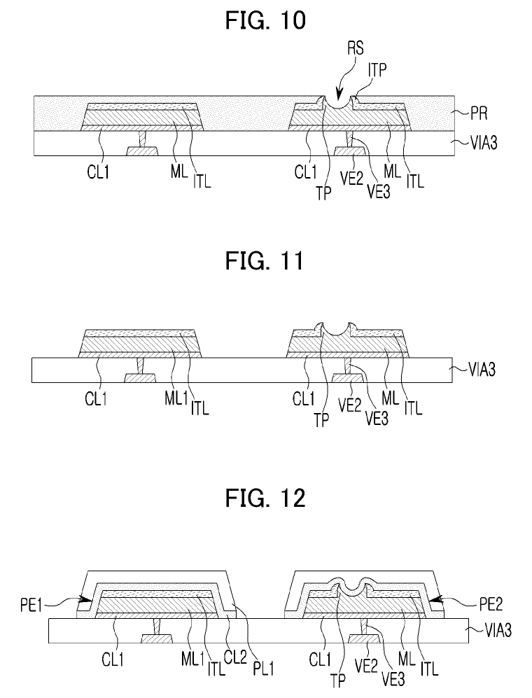

Referring to FIG. 10, the exposed protrusion PP of the metal layer ML may be etched. Accordingly, the protrusion PP may be at least partially removed to reduce a height of the protrusion PP.

According to embodiments, a concave recess RS may be formed by etching the protrusion PP, and a tip portion TP may be formed around the recess RS. An insulating tip portion ITP may be formed from the intermediate insulating layer ITL on an outer surface of the tip portion TP.

Referring to FIG. 11, the photoresist layer PR may be removed by an ashing process and/or a strip process. For example, the remaining photoresist layer PR may be entirely removed by the ashing and/or the strip process.

Referring to FIG. 12, a second conductive layer CL2 and a first protective layer PL1 may be sequentially formed on top surfaces of the third via insulating layer VIA3 and the preliminary pixel electrodes PPE1 and PPE2. The second conductive layer CL2 and the first protective layer PL1 may be formed by a deposition process such as a sputtering process, a CVD process, or the like, to include a transparent conductive oxide such as ITO and silicon oxide, respectively.

Thereafter, portions of the first protective layer PL1 and the second conductive layer CL2 between the neighboring preliminary pixel electrodes PPE1 and PPE2 may be etched by a photo-lithography process. Accordingly, the second conductive layer CL2 and the first protective layer PL1 may be formed to independently cover each of the first preliminary pixel electrode PPE1 and the second preliminary pixel electrodes PPE2.

Thus, a first pixel electrode PE1 and a second pixel electrode PE2 each of which may include a sequential stacked structure of the first conductive layer CL1, the metal layer ML, the intermediate insulating layer ITL, and the second conductive layer CL2 may be formed. The second conductive layer CL2 may entirely cover the intermediate insulating layer ITL, the metal layer ML and the first conductive layer CL1, and may be in contact with a side surface of the metal layer ML. The first protective layer PL1 may entirely cover a top surface of the second conductive layer CL2.

According to embodiments, the second conductive layer CL2 formed on the second pixel electrode PE2 may fill the recess RS formed in the metal layer ML.

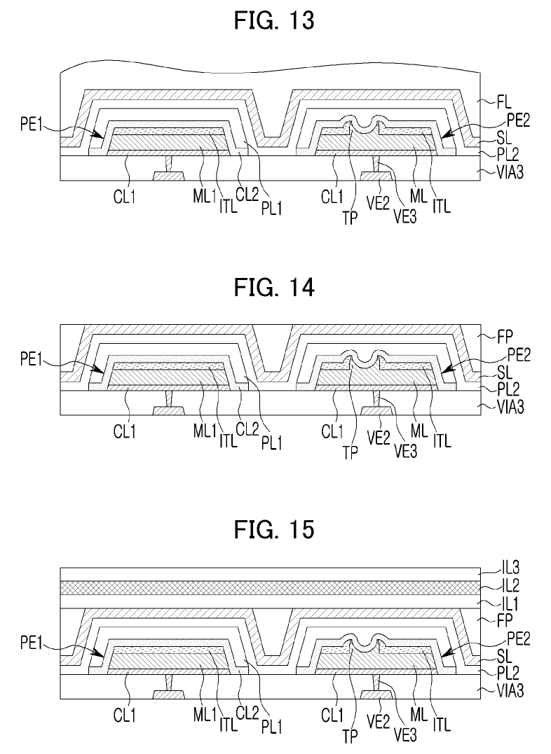

Referring to FIG. 13, a second protective layer PL2 and a blocking layer SL may be sequentially formed along top surfaces of the third via insulation layer VIA3 and the first protective layer PL1 to cover the pixel electrodes PE1 and PE2.

The second protective layer PL2 and the blocking layer SL may be formed by a deposition process such as a CVD process to include silicon oxide and silicon nitride, respectively.

Thereafter, a filling layer FL filling a space between the pixel electrodes PE1 and PE2 may be formed on the blocking layer SL. The filling layer FL may be formed by a coating process such as a spin coating process using an organosiloxane such as TEOS or an organosilane material.

Referring to FIG. 14, an upper portion of the filling layer FL may be removed by a polishing process such as chemical mechanical polishing CMP until a top surface of the blocking layer SL is exposed. Accordingly, the filling layer FL may be separated in each space between the pixel electrodes PE1 and PE2 to form a filling pattern FP.

The blocking layer SL may substantially serve as a polishing stopper layer. Top surfaces of the filling pattern FP and the blocking layer SL may be substantially coplanar with each other.

As described above, before performing the polishing process, a height of the protrusion PP formed by the hillock phenomenon of the metal layer ML may be reduced. Therefore, defects such as melting of the metal layer ML, generation of voids, etc., which may be generated by an exposure of the metal layer ML during the polishing process, may be prevented.

Referring to FIG. 15, a first insulating layer IL1, a second insulating layer IL2 and a third insulating layer IL3 may be sequentially formed on the blocking layer SL and the filling pattern FP. In some embodiments, the first insulating layer IL1, the second insulating layer IL2 and the third insulating layer IL3 may be formed by a deposition process such as a CVD process to include silicon oxide, silicon nitride and silicon oxide, respectively.

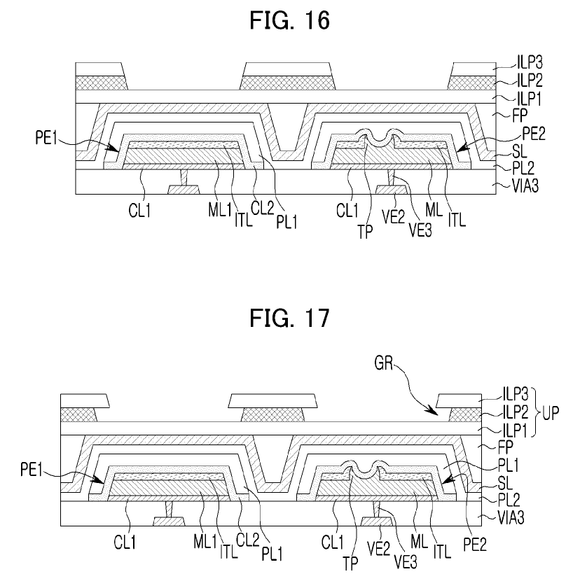

Referring to FIG. 16, a third insulating pattern ILP3 and a second insulating pattern ILP2 may be formed by etching the third insulating layer IL3 and the second insulating layer IL2.

In some embodiments, the third insulating layer IL3 may be etched to form a third insulating pattern ILP3. For example, the third insulating pattern ILP3 may be formed by a wet etching using an etchant having an etch selectivity for silicon oxide.

Thereafter, the second insulating layer IL2 may be etched to form a second insulating pattern ILP2. For example, the second insulating pattern ILP2 may be formed by a wet etching using an etchant having an etch selectivity for silicon nitride.

In some embodiments, the third insulating layer IL3 and the second insulating layer IL2 may be etched together by a dry etching to form the third insulating pattern ILP3 and the second insulating pattern ILP2.

Referring to FIG. 17, the second insulating pattern ILP2 may be additionally etched in a horizontal direction to form the groove GR. For example, the second insulating pattern ILP2 may be additionally etched by a wet etching using an etchant having a high etch selectivity for silicon nitride such as phosphoric acid. Accordingly, the second insulating pattern ILP2 may be retreated in the horizontal direction to form the groove GR. Lateral leakage between adjacent pixels may be prevented by the groove GR.

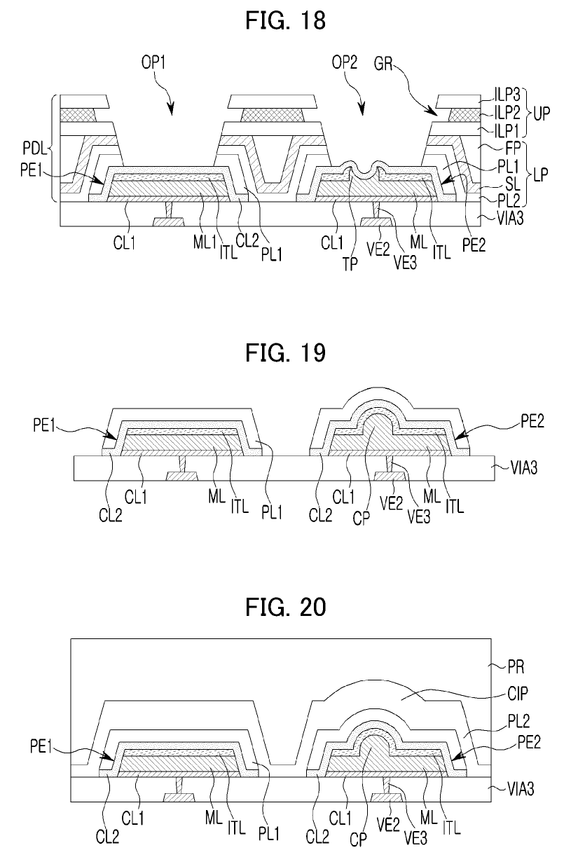

Referring to FIG. 18, the first insulating layer ILP1, the blocking layer SL, the second protective layer PL2, and the first protective layer PL1 may be sequentially etched to form a pixel defining layer PDL. A first opening OP1 and a second opening OP2 exposing top surfaces of the first pixel electrode PE1 and the second pixel electrode PE2, respectively, may be formed by the etching process. A light-emitting region or a pixel region a may be substantially defined by the first opening OP1 and the second opening OP2.

The pixel defining layer PDL may include an upper stack UP including the first insulating pattern ILP1, the second insulating pattern ILP2 and the third insulating pattern ILP3, and a lower stack LP including the first protective layer PL1, the second protective layer PL2, the blocking layer SL and the filling pattern FP.

Thereafter, as described with reference to FIG. 3, the light-emitting portion EL, the counter electrode CE and the encapsulation layer TFE may be sequentially formed on the pixel electrodes PE1 and PE2, and the pixel defining layer PDL.

FIGS. 19 to 23 are schematic cross-sectional views illustrating a method of manufacturing a display device according to embodiments. Detailed descriptions on processes and materials substantially the same as or similar to those described with reference to FIGS. 7 to 18 are omitted.

Referring to FIG. 19, preliminary pixel electrodes including the first conductive layer CL1, the metal layer ML and the intermediate insulating layer ITL which are sequentially formed on the third via insulating layer VIA3 and the third via electrode VE3 may be formed by processes substantially the same as or similar to those described with reference to FIG. 7.

Thereafter, the second conductive layer CL2 and the first protective layer PL1 may be formed on the preliminary pixel electrodes by a process substantially the same as or similar to that described with reference to FIG. 12.

Accordingly, the first and second pixel electrodes PE1 and PE2 including the first conductive layer CL1, the metal layer ML, the intermediate insulating layer ITL and the second conductive layer CL2 sequentially stacked on the third via electrode VE3 or the third via insulating layer VIA3 may be formed.

As described with reference to FIG. 7, the convex portion CP may be formed at the metal layer ML included in the second pixel electrode PE2 by, e.g., the Al hillock phenomenon. The second conductive layer CL2 and the first protective layer PL1 formed on the convex portion CP may also have convex curved surfaces.

Referring to FIG. 20, the second protective layer PL2 covering the first protective layer PL1 may be formed on the third via insulating layer VIA3. A portion of the second protective layer PL2 on the convex portion CP may be formed to include an convex insulating portion CIP.

Thereafter, a photoresist layer PR covering the second protective layer PL2 may be formed on the third via insulating layer VIA3.

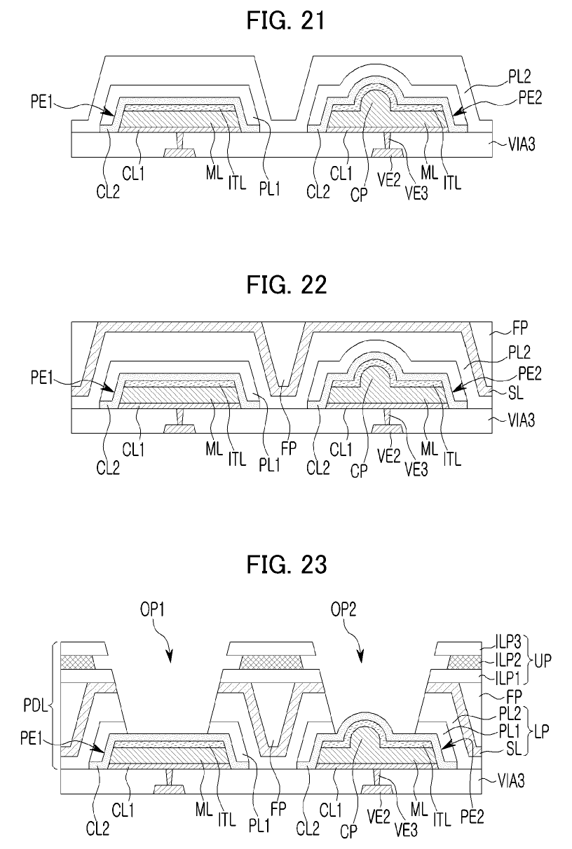

Referring to FIG. 21, an upper portion of the photoresist layer PR may be removed by an etch-back process.

The convex insulating portion CIP of the second protective layer PL2 may be removed together by the etch-back process. According to embodiments, the etch-back process may be performed until a top surface of the second protective layer PL2 is substantially planarized.

Thereafter, the photoresist layer PR may be removed through an ashing process and/or a strip process.

Referring to FIG. 22, processes substantially the same as or similar to those described with reference to FIGS. 13 and 14 may be performed.

According to embodiments, the blocking layer SL may be formed on the top surface of the second protective layer PL2, and a filling layer FP may be formed on the blocking layer SL. An upper portion of the filling layer may be polished or removed by performing a polishing process such as a CMP process until a top surface of the blocking layer SL is exposed to form the filling pattern FP.

Referring to FIG. 23, the pixel defining layer PDL may be formed by performing processes substantially the same as or similar to those described with reference to FIGS. 15 to 18. As described above, the pixel defining layer PDL may be formed to include the upper stack UP including the first insulating pattern ILP1, the second insulating pattern ILP2 and the third insulating pattern ILP3, and a lower stack LP including the first protective layer PL1, the second protective layer PL2, the blocking layer SL and the filling pattern FP.

Accordingly, the first opening OP1 and the second opening OP2 exposing the top surfaces of the first pixel electrode PE1 and the second pixel electrode PE2, respectively, may be formed.

According to embodiments, the convex portion CP of the metal layer ML may remain through the second opening OP2, and a convex curved portion of the second conductive layer CL2 formed on the convex portion CP may be exposed.

As described above, the convex insulating portion CIP formed on the convex portion CP may be substantially removed by using the etch-back process of the photoresist layer PR. Accordingly, after reducing a stepped portion caused by the convex portion CP, the subsequent process including the formation of the blocking layer SL and the CMP process may be performed.

Thus, melting of the metal layer ML and generation of voids due to exposure of the convex portion CP may be prevented during the CMP process.

In some embodiments, the convex portion CP may not overlap the second opening OP2. In this case, the convex portion CP may overlap the remaining blocking layer SL in the thickness direction. As described above, the blocking layer SL may be formed after the convex insulating portion CIP is substantially removed. Thus, even when the convex portion CP is disposed under the blocking layer SL, the blocking layer SL may have a substantially planarized top surface.

Thereafter, as described with reference to FIGS. 3 or 4, the light-emitting portion EL, the counter electrode CE and the encapsulation layer TFE may be sequentially formed on the pixel electrodes PE1 and PE2, and the pixel defining layer PDL.

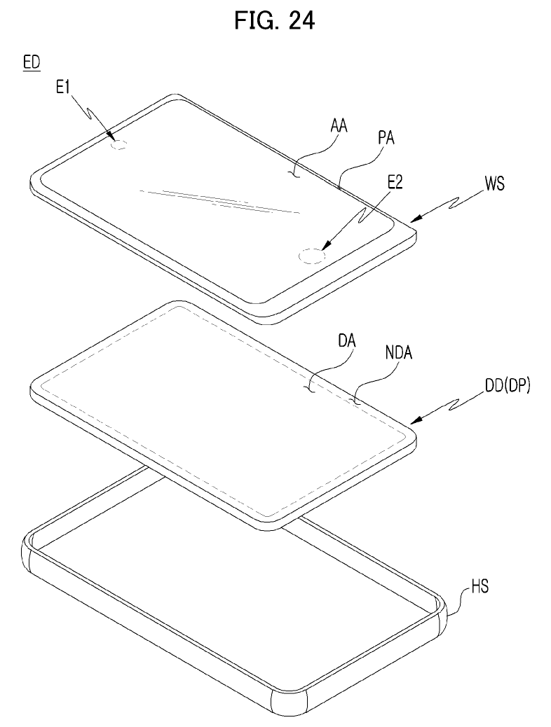

FIG. 24 is an exploded perspective view of a display device according to embodiments.

According to embodiments, an electronic device ED may be implemented in the form of a mobile phone (smart phone), a tablet, a PC, or the like, including the above-described display device.

Referring to FIG. 24, the electronic device ED may include a window structure WS, a display device DD and a housing HS. The display device DD may include a display panel DP including the transistor structures and the light-emitting element EE as described above. The housing HS, the display device DD and the window structure WS may be sequentially stacked in the third direction.

The window structure WS may provide an external display surface recognized by a user of a display, and may include a transparent material film. For example, the window structure WS may include glass (e.g., ultra-thin glass (UTG)), a hard coating film, a plastic film, or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the electronic device ED.

As described with reference to FIG. 1. the display device DD and the display panel DP may have a display area DA and a non-display area NDA. The display area DA of the display panel DP may substantially correspond to or overlap the active area AA of the window structure WS.

The non-display area NDA of the display panel DP may substantially correspond to or overlap the peripheral area PA of the window structure WS. In some embodiments, the peripheral area PA of the window structure WS may include a margin area that may not overlap the non-display area NDA of the display device DD or the display panel DP.

In some embodiments, functional device areas E1 and E2 may be disposed in an area corresponding to the active area AA of the window structure WS. For example, a first functional device area E1 may be disposed at one end portion of the active area AA and may be implemented, e.g., in the form of a camera hole. The second functional device area E2 may serve as a fingerprint sensing area.

For example, a sensor structure for a touch sensing or a fingerprint sensing may be disposed in the display panel DP or between the window structure WS and the display panel DP.

The housing HS may serve as a frame structure or a housing of the display device DD or the electronic device ED. A cover panel (not shown) may be disposed between the housing HS and the display panel DP. The housing HS or the cover panel may include a plate (e.g., an SUS plate) that supports the display panel DP, the printed circuit board 200 (see FIG. 1), or the like. The housing HS or the cover panel may include an elastic body for absorbing shock of the display device DD.

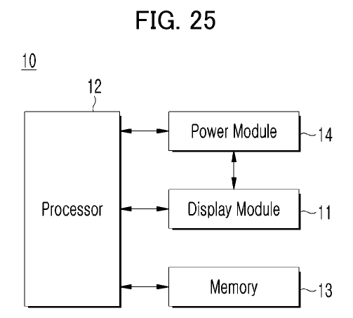

FIG. 25 is a block diagram of an electronic device in accordance with an embodiment.

Referring to FIG. 25, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal, and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

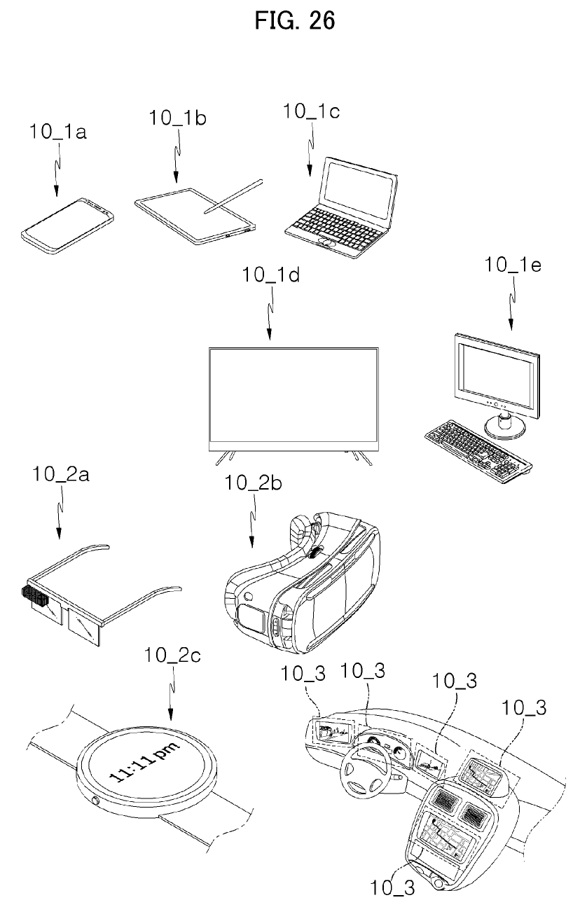

FIG. 26 is a schematic diagram of electronic devices in accordance with various embodiments.

Referring to FIG. 26, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a room mirror display, a head-up display, or the like. The electronic device may include a virtual reality glass or an augmented reality glass.

What is claimed is:

1. A method of manufacturing a display device, comprising:
forming a via insulating layer on a base substrate;
forming a pixel electrode, the forming the pixel electrode including:
forming a preliminary pixel electrode including a metal layer that has a protrusion on the via insulating layer;
forming a photoresist layer covering the preliminary pixel electrode on the via insulating layer;
removing an upper portion of the photoresist layer to expose an upper portion of the protrusion; and
etching the exposed upper portion of the protrusion to form the pixel electrode including the metal layer in which a height of the protrusion is reduced;
forming a light-emitting portion on the pixel electrode; and
forming a counter electrode on the light-emitting portion.

2. The method of claim 1, wherein the metal layer includes aluminum (Al).

3. The method of claim 1, wherein the forming the pixel electrode further comprises forming a conductive layer including a transparent conductive oxide on the metal layer in which the height of the protrusion is reduced.

4. The method of claim 3, wherein the preliminary pixel electrode further comprises an intermediate insulating layer formed on the metal layer and covering the protrusion, and
wherein the conductive layer is formed on the intermediate insulating layer to contact a side surface of the metal layer.

5. The method of claim 4, wherein the removing the upper portion of the photoresist layer to expose the upper portion of the protrusion comprises removing a portion of the intermediate insulating layer covering the upper portion of the protrusion.

6. The method of claim 1, wherein a recess is formed in a portion where the exposed upper portion of the protrusion is etched, and a tip portion surrounding the recess is formed by a remaining portion of the protrusion.

7. The method of claim 1, further comprising, before forming the light-emitting portion, forming a pixel defining layer partially covering the pixel electrode,
wherein the forming the pixel defining layer comprises:
sequentially forming a protective layer, a blocking layer and a filling layer on the pixel electrode;
polishing an upper portion of the filling layer until a top surface of the blocking layer is exposed to form a filling pattern; and
partially etching the blocking layer and the protective layer to form an opening exposing a top surface of the pixel electrode.

8. The method of claim 7, wherein the forming the pixel defining layer comprises sequentially forming a first insulating layer, a second insulating layer and a third insulating layer that includes an insulating inorganic oxide, an insulating inorganic nitride and an insulating inorganic oxide, respectively, on a stopper layer and the filling pattern, and forming the opening comprises partially etching the third insulating layer, the second insulating layer and the first insulating layer before partially etching the blocking layer and the protective layer to form a third insulating pattern, a second insulating pattern and a first insulating pattern.

9. The method of claim 1, wherein the removing the upper portion of the photoresist layer to expose the upper portion of the protrusion comprises an etch-back process.

10. A method of manufacturing a display device, comprising:
forming a via insulating layer on a base substrate;
forming a pixel electrode including a metal layer that has a convex portion on the via insulating layer;
forming a protective layer covering the pixel electrode and having a convex insulating portion on the convex portion;
forming a photoresist layer on the protective layer;
removing the convex insulating portion while removing an upper portion of the photoresist layer;
etching the protective layer to form an opening exposing a top surface of the pixel electrode;
forming a light-emitting portion on the exposed pixel electrode; and
forming a counter electrode on the light-emitting portion.

11. The method of claim 10, wherein the removing the convex insulating portion while removing an upper portion of the photoresist layer comprises an etch-back process.

12. The method of claim 10, further comprising, after the removing the convex insulating portion while removing the upper portion of the photoresist layer:
removing the remaining photoresist layer;
forming a blocking layer on the protective layer;
forming a filling layer that fills a space from which the remaining photoresist layer is removed on the blocking layer; and
polishing the filling layer until a top surface of the blocking layer is exposed to form a filling pattern.

13. The method of claim 12, wherein the etching the protective layer to form the opening comprises etching the blocking layer before etching the protective layer.

14. The method of claim 10, wherein the metal layer includes aluminum (Al).

15. The method of claim 10, wherein the forming the pixel electrode comprises forming a conductive layer covering the convex portion and including a transparent conductive oxide on the metal layer.

16. The method of claim 15, wherein the forming the pixel electrode further comprises forming an intermediate insulating layer covering the convex portion between the conductive layer and the metal layer, and
wherein the conductive layer contacts a side surface of the metal layer.

17. An electronic device, comprising:
a display device;
a memory; and
a processor executing data contained in the memory to control an operation of the display device, wherein the display device comprises:
a base substrate;
a transistor structure on the base substrate;
a pixel electrode comprising a metal layer electrically connected to the transistor structure, the metal layer including a tip portion or a convex portion that protrudes from a top surface thereof;
a light-emitting portion on the pixel electrode; and
a counter electrode on the light-emitting portion.

18. The electronic device of claim 17, wherein the metal layer includes the tip portion, and has a recess surrounded by the tip portion,
wherein the pixel electrode comprises:
an intermediate insulating layer covering a side surface of the tip portion on the top surface of the metal layer; and
a conductive layer including a transparent conductive oxide, filling the recess on the intermediate insulating layer and contacting a side surface of the metal layer.

19. The electronic device of claim 17, wherein the metal layer includes the convex portion,
wherein the pixel electrode further comprises:
an intermediate insulating layer covering the convex portion on the top surface of the metal layer; and
a conductive layer disposed on the intermediate insulating layer, including a transparent conductive oxide and contacting a side surface of the metal layer, and
wherein each of the intermediate insulating layer and the conductive layer has a convex curved surface on the convex portion.

20. The electronic device of claim 17, wherein the electronic device includes virtual reality or augmented reality glasses, a smartphone, a tablet personal computer (PC), a laptop, a television, a desk monitor, smart glasses, a head-mounted display, a smart watch, or a vehicle display.
